(19) United States
(12) Patent Application Publication
(10) Pub. No.: US 2009/0315026 A1
(43) Pub. Date: Dec. 24, 2009

(54) THIN FILM TRANSISTOR, METHOD OF MANUFACTURING THE SAME, AND FLAT PANEL DISPLAY DEVICE HAVIING THE SAME

(75) Inventors: Jae-Kyeong JEONG, Suwon-si (KR); Hyun-Soo Shin, Suwon-si (KR); Yeon-gon Mo, Suwon-si (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Suwon-si (KR)

(21) Appl. No.: 12/352,819

(22) Filed: Jan. 13, 2009

(30) Foreign Application Priority Data
Jun. 18, 2008 (KR) 2008-57250

(51) Int. Cl. H01L 29/786

(52) U.S. Cl. 257/43; 257/E29.296

(57) ABSTRACT

A thin film transistor, a method of manufacturing the same, and a flat panel display device having the same use an oxide semiconductor as an active layer, wherein the thin film transistor includes: an oxide semiconductor layer formed on a substrate and having a channel region, a source region, and a drain region; a gate electrode insulated from the oxide semiconductor layer by a gate insulating layer; an ohmic contact layer formed on the source region and the drain region of the oxide semiconductor layer; and a source electrode and a drain electrode coupled to the source region and the drain region through the ohmic contact layer, the ohmic contact layer being formed of a metal having a lower work function lower than work functions of the source electrode and the drain electrode.

### CROSS-REFERENCE TO RELATED APPLICATIONS

This application claims the benefit of Korean Patent Application No. 2008-57250, filed on Jun. 18, 2008, in the Korean Intellectual Property Office, the content of which is incorporated herein by reference.

### BACKGROUND OF THE INVENTION

1. Field of the Invention

Aspects of the present invention relate to a thin film transistor, a method of manufacturing the same, and a flat panel display device having the same, and particularly relates to a thin film transistor that uses an oxide semiconductor as an active layer, a method of manufacturing the same, and a flat panel display device having the same.

2. Description of the Related Art

Generally, in a thin film transistor manufactured by a semiconductor process, an active layer having a channel region, a source region, and a drain region is formed of a semiconductor, such as amorphous silicon or poly-silicon. However, if the active layer is formed of amorphous silicon, the active layer has low mobility so that it is difficult to operate a driving circuit at a high speed. Also, if the active layer is formed of poly-silicon, the active layer has a high mobility but a non-uniform threshold voltage so that a separate compensation circuit is necessary.

As an example, in the case of applying the thin film transistor with an active layer of poly-silicon to a display device, a need exists for a compensation circuit having five thin film transistors and two capacitors in order to maintain a uniform threshold voltage and the high mobility. Accordingly, a complicated process and a number of masks are used thus increasing manufacturing cost and decreasing yield.

Recently, in order to solve these problems, a study on a use of oxide semiconductor as the active layer has been conducted.

The thin film transistor using zinc oxide (ZnO) or an oxide semiconductor mainly constituted by the zinc oxide (ZnO) as the active layer is disclosed in the Japanese Patent Publication No. 2004-273614.

However, a conventional thin film transistor using the oxide semiconductor as the active layer has poor ohmic contact with a metal electrode due to a wide band gap of the oxide semiconductor.

### SUMMARY OF THE INVENTION

Aspects of the present invention provide a thin film transistor, a method of manufacturing the same, and a flat panel display device having the same capable of improving ohmic contact characteristics of an oxide semiconductor layer and a metal electrode.

Aspects of present invention provide a thin film transistor including: a substrate; an oxide semiconductor layer formed on the substrate and having a channel region, a source region, and a drain region; a gate insulating layer formed on the substrate to cover the oxide semiconductor layer; a gate electrode formed on the gate insulating layer and insulated from the oxide semiconductor layer by the gate insulating layer; an ohmic contact layer formed on the source region and the drain region of the oxide semiconductor layer; and a source electrode and a drain electrode respectively electrically coupled to the source region and the drain region through the ohmic contact layer, wherein the ohmic contact layer is formed of a metal having a lower work function than work functions of the source electrode and the drain electrode.

Aspects of present invention provide a method of manufacturing a thin film transistor including: forming a gate electrode on a substrate; forming a gate insulating layer on the gate electrode; forming an oxide semiconductor layer having a channel region, a source region, and a drain region on the gate insulating layer; forming an ohmic contact layer on the source region and the drain region of the oxide semiconductor layer; and forming a source electrode and a drain electrode respectively electrically coupled to the source region and the drain region through the ohmic contact layer, wherein the ohmic contact layer is formed of a metal having a lower work function than the source electrode and the drain electrode.

Aspects of present invention provide a flat panel display device having a thin film transistor according to yet another aspect of the present invention including: a first substrate having disposed thereon first and second conductive lines, the first conductive lines disposed to cross the second conductive lines, a plurality of pixels, each of the plurality of pixels having a first electrode and being defined by the first conductive lines and the second conductive lines, a plurality of thin film transistors electrically coupled to the first electrodes to control signals supplied to each of the pixels, respectively; a second substrate having a second electrode formed thereon; and a liquid crystal layer disposed in a sealed space between the first electrode and the second electrode, wherein each of the thin film transistors includes: a gate electrode electrically connected to one of the first and second conductive lines; an ohmic contact layer formed on the source region and the drain region of the oxide semiconductor layer; and a source electrode and a drain electrode respectively electrically coupled to the source region and the drain region through the ohmic contact layer, one of the source electrode and the drain electrode being electrically connected to the other of the first and second conductive lines, and the other of the source electrode and the drain electrode being electrically connected to the first electrode, wherein the ohmic contact layer is formed of a metal having a lower work function than work functions of the source electrode and the drain electrode.

Aspects of present invention provide a flat panel display device having a thin film transistor according to yet another aspect of the present invention including: a first substrate having disposed thereon an organic light emitting element including a first electrode, an organic thin film layer, and a second electrode, scan and data lines, and a thin film transistor to control operation of the organic light emitting element; and a second substrate disposed to face the first substrate, wherein the thin film transistor includes: a gate electrode electrically connected to one of the scan lines; an ohmic contact layer formed on a source region and a drain region of an oxide semiconductor layer; and a source electrode and a drain electrode respectively electrically coupled to the source region and the drain region through the ohmic contact layer, one of the source electrode and the drain electrode being electrically connected to one of the data lines, and the other of the source electrode and the drain electrode being electrically connected to the first electrode, wherein the ohmic contact layer is formed of a metal having a lower work function than work functions of the source electrode and the drain electrode.

Aspects of present invention provide a thin film transistor, including: a substrate; a gate electrode formed on the substrate; a gate insulating layer formed on the substrate to cover the gate electrode; an oxide semiconductor layer formed on the gate insulating layer, the oxide semiconductor layer being insulated from the gate electrode by the gate insulating layer, and the oxide semiconductor layer having a channel region, a source region, and a drain region; an ohmic contact layer formed on the source region and the drain region of the oxide semiconductor layer; and a source electrode and a drain electrode respectively electrically coupled to the source region and the drain region through the ohmic contact layer, wherein the ohmic contact layer is formed of a metal having a lower work function than work functions of the source electrode and the drain electrode.

Aspects of present invention provide a method of manufacturing a thin film transistor, the method including: forming an oxide semiconductor layer having a channel region, a source region, and a drain region on a substrate; forming a gate insulating layer on the oxide semiconductor layer; forming a gate electrode on the gate insulating layer; forming via holes in the gate insulating layer to expose portions of the source region and the drain region; forming an ohmic contact layer on the exposed portions of the source region and the drain region; and forming a source electrode and a drain electrode respectively electrically coupled to the source region and the drain region through the ohmic contact layer.

Aspects of present invention provide a method of manufacturing a thin film transistor, the method including: forming an oxide semiconductor layer having a channel region, a source region, and a drain region on a substrate; forming an ohmic contact layer on the source region and the drain region; forming a gate insulating layer on the oxide semiconductor layer; forming a gate electrode on the gate insulating layer; forming via holes in the gate insulating layer to expose portions of the ohmic contact layer on the source region and the drain region; and forming a source electrode and a drain electrode respectively electrically coupled to the source region and the drain region through the ohmic contact layer, wherein the ohmic contact layer is formed of a metal having a lower work function than work functions of the source electrode and the drain electrode.

According to aspects of the present invention, the ohmic contact layer is formed between the oxide semiconductor layer and the metal electrode and of the metal or an alloy thereof having a low function. Therefore, height of a Schottky barrier is reduced by the ohmic contact layer so that contact resistance between the oxide semiconductor layer and the source and drain electrodes is lowered. Thereby, a current-voltage characteristic is improved so that an electrical characteristic of the device may be improved.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of a thin film transistor according to an embodiment of the present invention;

FIG. 2 is a cross-sectional view of a thin film transistor according to an embodiment of the present invention;

FIG. 3 is a cross-sectional view of a thin film transistor according to an embodiment of the present invention;

FIG. 4 is a cross-sectional view of a thin film transistor according to an embodiment of the present invention;

FIGS. 5A to 5E are cross-sectional views illustrating a method of manufacturing the thin film transistor according to aspects of the present invention;

FIGS. 6 to 9 are band diagrams before and after junction of a metal and an oxide semiconductor;

FIG. 10 is a perspective view of a flat panel display device having the thin film transistor according to aspects of the present invention;

FIGS. 11A and 11B are perspective views of a flat panel display device having the thin film transistor according to aspects of the present invention; and

FIG. 12 is a cross-sectional view of an organic light emitting element in FIG. 11A.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on,” “formed on,” or “disposed on” another element, it can be directly on, formed directly on, or disposed directly on another element or one or more intervening elements may be disposed therebetween. Also, when an element is referred to as being “connected to,” “coupled to,” or “electrically coupled to” another element, it can be directly connected to another element or be indirectly connected to another element with one or more intervening elements interposed therebetween. Hereinafter, like reference numerals refer to like elements.

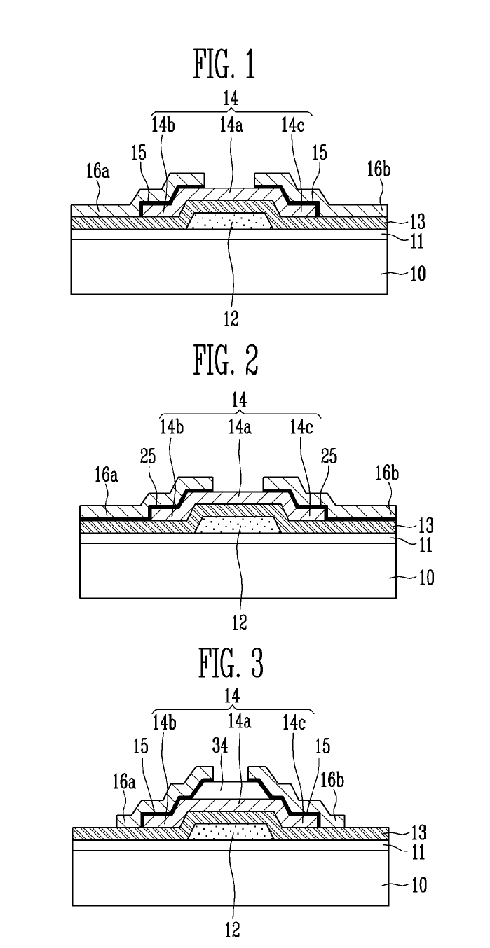

FIG. 1 is a cross-sectional view of a thin film transistor according to an embodiment of the present invention, wherein an example of a bottom gate structure is shown. Although explained with respect to a bottom gate thin film transistor, aspects of the present invention may also be applied to a top gate thin film transistor. A buffer layer 11 is formed on a substrate 10, and a gate electrode 12 is formed on the buffer layer 11. A gate insulating layer 13 is formed on an upper surface of the substrate 10 on which the gate electrode 12 is formed. An oxide semiconductor layer 14 is formed as an active layer having a channel region 14a, a source region 14b, and a drain region 14c and formed on the gate insulating layer 13 corresponding to the gate electrode 12. An ohmic contact layer 15 is formed on the source region 14b and the drain region 14c of the oxide semiconductor layer 14. Also, source and drain electrodes 16a and 16b are formed to contact the source region 14b and the drain region 14c through the ohmic contact layer 15.

The oxide semiconductor layer 14 includes zinc oxide (ZnO), and may be doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V). The oxide semiconductor layer 14 may be formed of ZnO, ZnGaO, ZnInO, ZnSnO, GaInZnO, CdO, InO, GaO, SnO, AgO, CuO, GeO, GdO, HfO, etc., for example.

The ohmic contact layer 15 reduces contact resistance between the source region 14b and the drain region 14c of the oxide semiconductor layer 14 and the source and drain electrodes 16a and 16b, which are made of a metal. Accordingly, the ohmic contact layer 15 is formed of a metal having a lower work function than a work function of a metal from which the source and drain electrodes 16a and 16b are formed.

In the case where the source and drain electrodes 16a and 16b are formed of a metal, such as molybdenum (Mo), tungsten (W), aluminum (Al), titanium (Ti), etc., the work functions of these metals is approximately 4 eV or more. Therefore, the ohmic contact layer 15 is formed of a metal with work function of 2 to 4 eV. Such a metal includes an alkali metal such as calcium (Ca) (2.9 eV), magnesium (Mg) (3.7 eV), potassium (K) (2.3 eV), lithium (Li) (2.9 eV), etc. However, since such an alkali metal has a chemically high reactivity, the alkali metal may be easily changed by a chemical reaction. Therefore, the ohmic contact layer 15 may be formed of an alloy, such as magnesium-silver (Mg—Ag), lithium-aluminum (Li—Al), aluminum-silver (Al—Ag), lithium-fluorine (LiF), etc., in order to prevent such chemical change.

FIG. 2 is a cross-sectional view of a thin film transistor according to an embodiment of the present invention. Herein, only the differences between the structures shown in FIG. 1 and FIG. 2 will be described.

The thin film transistor in FIG. 1 has a structure that the ohmic contact layer 15 is formed only on the source region 14b and the drain region 14c of the oxide semiconductor layer 14. On the other hand, the thin film transistor in FIG. 2 has a structure that an ohmic contact layer 25 is formed on lower surfaces of the source and drain electrodes 16a and 16b. The ohmic contact layer 25 is formed to overlap the source and drain electrodes 16a and 16b. Therefore, it is possible to pattern the ohmic contact layer 25 and the source and drain electrodes 16a and 16b with one mask, thereby decreasing mask numbers and process steps as compared to FIG. 1.

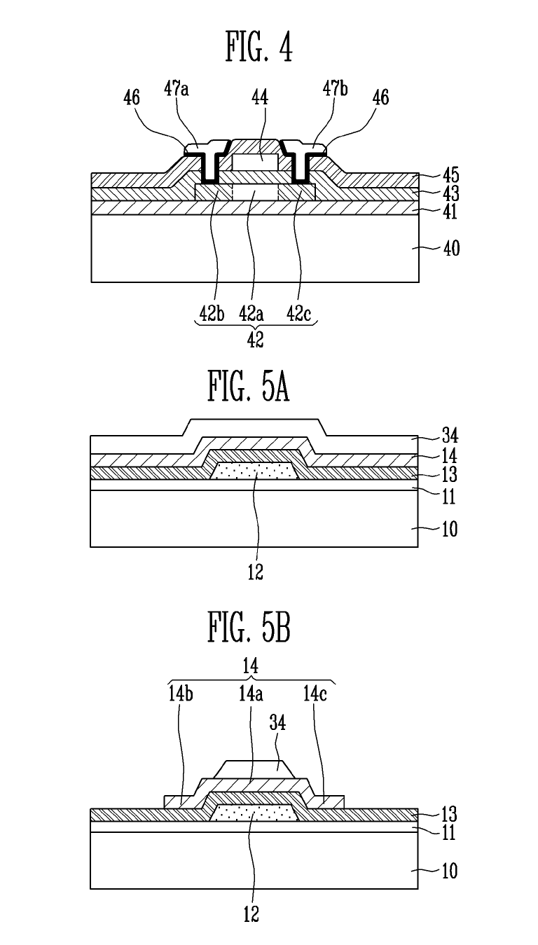

FIG. 3 is a cross-sectional view of a thin film transistor according to an embodiment of the present invention. Herein, only the differences between the structures shown in FIG. 1 and FIG. 3 will be described. While the thin film transistor in FIG. 1 has a structure that the channel region 14a of the oxide semiconductor layer 14 is exposed, the thin film transistor in FIG. 3 has a structure that a passivation layer 34 is formed on the channel region 14a of the oxide semiconductor layer 14. The passivation layer 34 is formed of an inorganic material or an insulating organic material, such as a polyimide-based resin, etc.

The oxide semiconductor layer 14 is easily damaged by plasma or easily etched by acid chemicals, etc. Therefore, in the structure that the oxide semiconductor layer 14 is exposed, when forming a thin film thereon or etching a formed thin film, damage may occur so that a change in an electrical characteristic, such as increase of carriers, occurs. Because of such a change in the electrical characteristic of the oxide semiconductor layer 14, an electrical characteristic of the thin film transistor may be deteriorated and a dispersive degree of the electrical characteristics in the substrate may be deteriorated.

However, according to the above embodiment, in an etching process forming the source and drain electrodes 16a and 16b, the channel region 14a of the oxide semiconductor layer 14 is protected by the passivation layer 34 and at the same time, the passivation layer 34 may be used as an etch stop layer. Therefore, the damage of the oxide semiconductor layer 14 by the plasma or the acid chemicals is effectively prevented and at the same time, the process is simplified.

FIG. 4 a cross-sectional view of a thin film transistor according to an embodiment of the present invention, wherein an example of a top gate structure is shown. A buffer layer 41 is formed on a substrate 40, and an oxide semiconductor layer 42 is formed as an active layer having a channel region 42a, a source region 42b, and a drain region 42c on the buffer layer 41. A gate insulating layer 43 is formed on an upper surface of the oxide semiconductor layer 42, and a gate electrode 44 is formed on the gate insulating layer 43 on an upper surface of the oxide semiconductor layer 42, i.e., the gate electrode is formed on the gate insulating layer 43 in an area corresponding to the oxide semiconductor layer 42. An insulating layer 45 is formed on an upper surface to cover the gate electrode 44, and contact holes are formed in the insulating layer 45 and the gate insulating layer 43 so that portions of the source region 42b and the drain region 42c of the oxide semiconductor layer 42a re exposed. An ohmic contact layer 46 is formed to cover surfaces of the contact holes formed in the insulating layer 45 and the gate insulating layer 43. The ohmic contact layer 46 further covers the exposed portions of the source region 42b and the drain region 42c of the oxide semiconductor layer 42 exposed through the contact holes. Source and drain electrodes 47a and 47b are formed to be coupled to the source region 42b and the drain region 42c through the ohmic contact layer 46.

Although a case where the ohmic contact layer 46 is formed to correspond with the source and drain electrodes 47a and 47b is shown in FIG. 4, the ohmic contact layer 46 may also be formed only on the exposed portions of the oxide semiconductor layer 42. Further, the ohmic contact layer 46 may be formed on the entire source and drain regions 14b and 14c of the oxide semiconductor region 14 between the source and drain regions 14b and 14c and the gate insulating layer 43.

The oxide semiconductor layer 42 includes zinc oxide (ZnO), and may be doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V). The oxide semiconductor layer 42 may be formed of ZnO, ZnGaO, ZnInO, ZnSnO, GaInZnO, CdO, InO, GaO, SnO, AgO, CuO, GeO, GdO, HfO, etc., for example.

The ohmic contact layer 46 reduces contact resistance between the source region 42b and the drain region 42c of oxide semiconductor layer 42 and the source and drain electrodes 47a and 47b, which are made of a metal. Accordingly, the ohmic contact layer 46 is formed of a metal having a work function lower than a work function of a metal from which the source and drain electrodes 47a and 47b are formed.

In the case where the source and drain electrodes 47a and 47b are formed of a metal, such as molybdenum (Mo), tungsten (W), aluminum (Al), titanium (Ti), etc., the work functions of these metals are approximately 4 eV or more. Therefore, the ohmic contact layer 15 is formed of a metal with the work function of about 2 to 4 eV. Such a metal includes an alkali metal, such as calcium (Ca) (2.9 eV), magnesium (Mg) (3.7 eV), potassium (K) (2.3 eV), lithium (Li) (2.9 eV), etc. However, since such an alkali metal has a chemically high reactivity, it may be easily changed by a chemical reaction. Therefore, the ohmic contact layer 15 may be formed of an alloy, such as magnesium-silver (Mg—Ag), lithium-aluminum (Li—Al), aluminum-silver (Al—Ag), lithium-fluorine (LiF), etc., in order to prevent such chemical change.

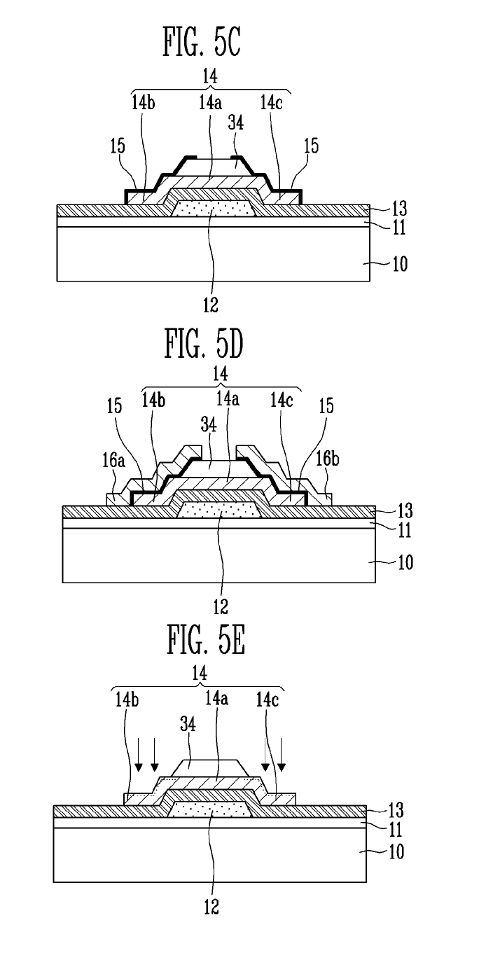

FIGS. 5A to 5E are cross-sectional views illustrating a method of manufacturing a thin film transistor according to aspects of the present invention. Herein, the structure in FIG. 3 will be explained as an example.

Referring to FIG. 5A, after forming the buffer layer 11 on the substrate 10, the gate electrode 12 is formed on the buffer layer 11. The gate insulating layer 13, the oxide semiconductor layer 14, and the passivation layer 34 are sequentially formed on the upper surface of the substrate having the gate electrode 12 formed thereon.

As the substrate 10, a semiconductor substrate, such as silicon (Si), an insulating substrate, such as glass or plastic, or a metal substrate may be used. The gate electrode 12 is formed of a metal such, as Al, Cr, MoW, etc., and the gate insulating layer 13 is formed of an insulating material, such as SiO₂, SiNₓ, GaO₃, etc. The oxide semiconductor layer 14 includes zinc oxide (ZnO), wherein the ZnO may be doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V). The oxide semiconductor layer 14 is formed of ZnO, ZnGaO, ZnInO, ZnSnO, GaInZnO, CdO, InO, GaO, SnO, AgO, CuO, GeO, GdO, HfO, etc., for example. Also, the passivation layer 34 is formed of an inorganic material or an insulating organic material, such as a polyimide-based resin, etc.

Referring to FIG. 5B, the oxide semiconductor layer 14 is patterned so that a channel region 14a, a source region 14b, and a drain region 14c are defined, and the passivation layer 34 is patterned so that it remains only on the channel region 14a of the oxide semiconductor 14.

Referring to FIG. 5C, after forming the ohmic contact layer 15 over the whole upper surface of substrate having the patterned passivation layer 34 and the patterned oxide semiconductor layer 14, the ohmic contact layer 15 is patterned so that it remains only on the source region 14b and the drain region 14c of the oxide semiconductor layer 14 and the passivation layer 34, i.e., the ohmic contact layer 15 is patterned to correspond to areas on which source and drain electrodes 16a and 16b are to be formed. However, aspects of the present invention are not limited thereto such that the ohmic contact layer 15 may be patterned as described above with respect to FIGS. 1-4.

Referring to FIG. 5D, the source and drain electrodes 16a and 16b are formed to be coupled to the source region 14b and the drain region 14c through the ohmic contact layer 15. The source and drain electrodes 16a and 16b are formed of a metal, such as molybdenum (Mo), tungsten (W), aluminum (Al), titanium (Ti), or are formed of an alloy thereof. The source and drain electrodes 16a and 16b may be formed in a stacked structure of the metal and/or alloy thereof. Further, in the case of a transparent thin film transistor, the source and drain electrodes 16a and 16b may be formed of a transparent conductive material, such as indium tin oxide (ITO), indium zinc oxide (IZO), indium tin zinc oxide (ITZO), etc.

As another embodiment of the present invention, referring to FIG. 5E, it is possible to irradiate plasma on the exposed source and drain regions 14b and 14c on both sides of the passivation layer 34 in the operation of patterning the oxide semiconductor layer 14 and the passivation layer 34 as in FIG. 5B. In such case, oxygen vacancy occurs due to lattice damage by the plasma. Due to an increase in effect carrier, electric conductivities of surfaces of the source region 14b and the drain region 14c increase so that contact resistance between the source region 14b and the drain region 14c of the oxide semiconductor layer 14 and the source and drain electrodes 16a and 16b may be effectively reduced.

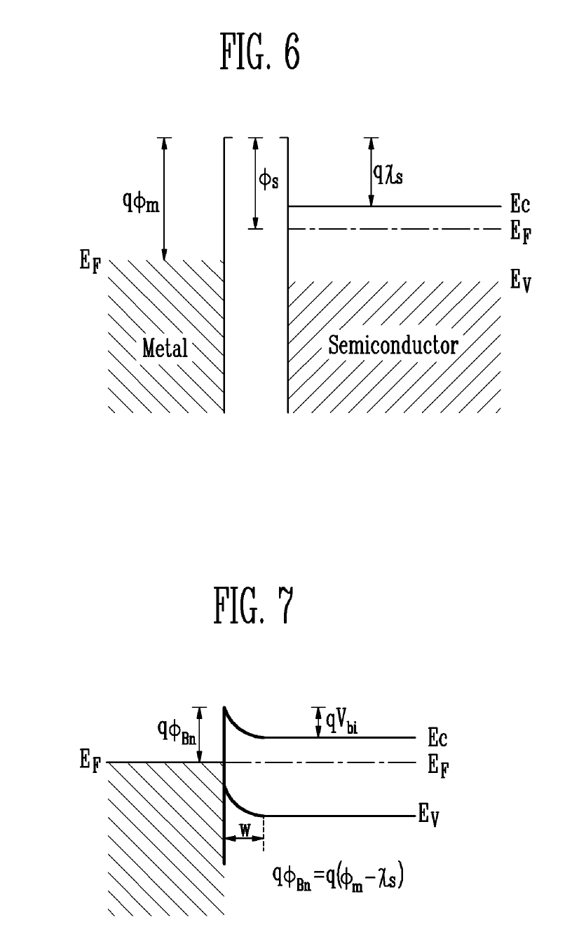

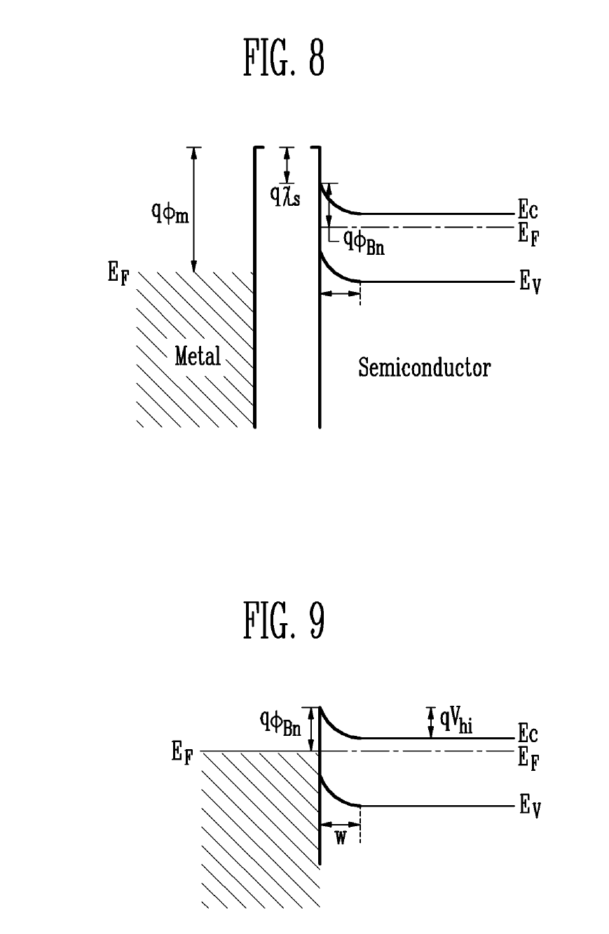

Next, aspects of the present invention capable of effectively reducing the contact resistance between the oxide semiconductor layer 14 and the source and drain electrodes 16a and 16b will be described with reference to FIGS. 6 to 9.

FIG. 6 is a band diagram before junction of a metal and an oxide semiconductor (for example, ZnO), wherein the work function of the metal is larger than that of an n-type oxide semiconductor (φm>φs). The conduction band E_{C} and the valence band E_{V} are indicated for the semiconductor, and the Fermi energies E_{F} of both the metal and the semiconductor are indicated. A general metal corresponds to such a band diagram.

FIG. 7 is a band diagram after the junction of the metal and the oxide semiconductor (for example, ZnO), wherein some electrons of the oxide semiconductor are diffused toward the metal so that a depletion region is formed in the oxide semiconductor in the vicinity of the interface between metal and the oxide semiconductor. As a result, a Schottky barrier is formed so that in the case of no interfacial states, an ohmic contact characteristic is not indicated. At this time, the contact resistance Rc may be indicated as in Equation. 1 below.

$$Rc = [ \frac{k}{qAET} ] exp ( q \frac{{Φ}_{Bn}}{kT} ) \qquad [ Equation 1 ]$$

Herein, T indicates a temperature, A indicates a Richardson constant, k indicates a Boltzmann constant, and qφ_{Bn} indicates the Schottky barrier.

In the Equation 1, since it is possible to approximate qΦ_{Bn}=qΦ_{M}−qχₛ (qΦ_{M} indicates the work function of the metal, and qχₛ. indicates electron affinity), a height of the Schottky barrier is determined by the electron affinity of the metal and the oxide semiconductor. As the work function of the metal becomes smaller, the height of the Schottky barrier is reduced so that the contact resistance is reduced.

FIG. 8 is a band diagram after the junction of the metal and the oxide semiconductor (for example, ZnO) in the case where a number of surface states exist on a surface of the oxide semiconductor, wherein the electron on the surface of the oxide semiconductor is trapped in an interface state so that the depletion region is formed. This is referred to as Fermi level pinning.

FIG. 9 is a band diagram after the junction of the metal and a Fermi level pinned oxide semiconductor. At this time, the height of the Schottky barrier is independent of the work function of the metal. This is referred to as the Bardeen limit.

As described above, according to aspects of the present invention, the ohmic contact layer is formed of the metal with a low work function between the oxide semiconductor layer and the metal electrode. The height of the Schottky barrier is reduced by the ohmic contact layer so that the contact resistance between the oxide semiconductor layer and the metal electrode is reduced. Thereby, current-voltage characteristics of the thin film transistor may be improved.

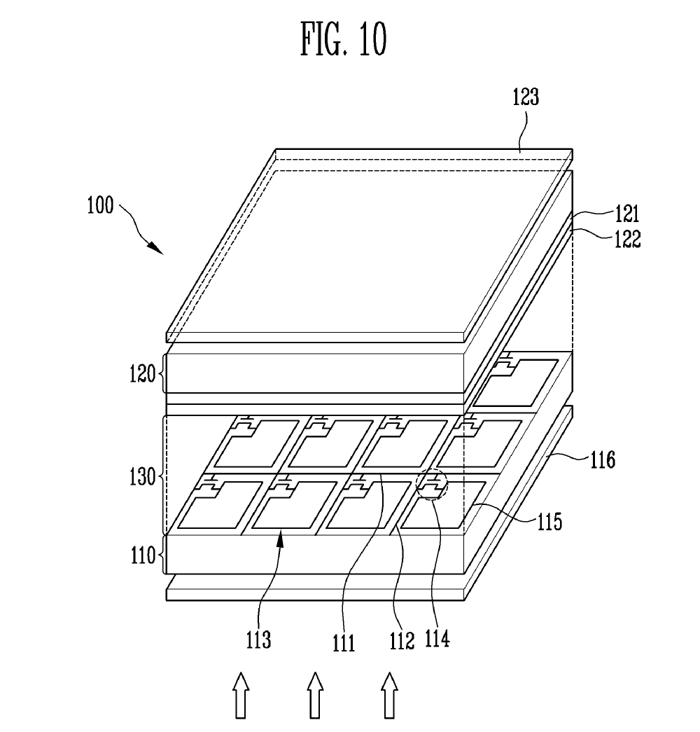

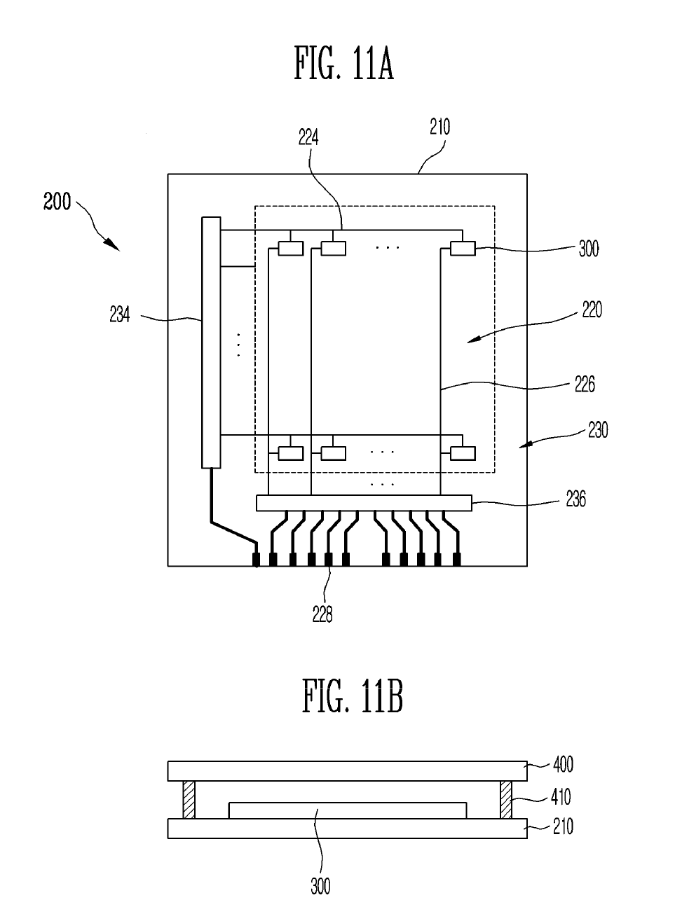

FIG. 10 is a perspective view of a flat panel display device having a thin film transistor according to aspects of the present invention. Hereinafter, a display panel 100 to display an image will be described.

The display panel 100 comprises two substrates 110 and 120 disposed to face each other and a liquid crystal layer 130 disposed between the two substrates 110 and 120. In the display panel 100, a pixel region 113 is defined by a plurality of scan lines 111 and a plurality of data lines 112 arranged in a matrix form on the substrate 110. Also, a thin film transistor 114 to control signals supplied to each pixel and a pixel electrode 115 coupled to the thin film transistor 114 are formed on the substrate 110 in each of the pixel regions 113.

The thin film transistor 114 has any one of the structures in FIGS. 1 to 4, and may be manufactured according to the method described with reference to FIGS. 5A to 5E.

Also, a color filter 121 and a common electrode 122 are formed on the substrate 120. Polarizing plates 116 and 123 are formed on rear surfaces of the substrates 110 and 120, respectively, and a backlight (not shown) is disposed as a light source under the polarizing plate 116.

Meanwhile, a driver (LCD drive IC, not shown) to drive the display panel 100 is mounted in the circumferential area of the pixel region 113 of the display panel 100. The driver converts an electrical signal provided from the outside into a scan signal and a data signal to supply them to the scan lines 111 and the data lines 112.

FIGS. 11A and 11B are a plan view and a cross-sectional view of a flat panel display device having a thin film transistor according to aspects of the present invention. Hereinafter, a display panel 200 to display an image will be described.

Referring to FIG. 11A, a substrate 210 includes a pixel region 220 and a non-pixel region 230 surrounding the pixel region 220. A plurality of organic light emitting elements 300 coupled in a matrix form between scan lines 224 and data lines 226 are formed on the substrate 210 in the pixel region 220. A scan line 224 and a data line 226 extends from the pixel region 220 to the non-pixel region 230 and are supplied with signals from a scan driver 234 and a data driver 236, respectively. A power supply line (not shown) supplies power to the organic light emitting element 300. The scan driver 234 and a data driver 236 process signals provided from the outside through a pad 228 to supply the processed signals to the scan line 224 and the data line 226, respectively. The scan driver 234, the data driver 236, the power supply line, and the pad are formed on the substrate 210 in the non-pixel region 230.

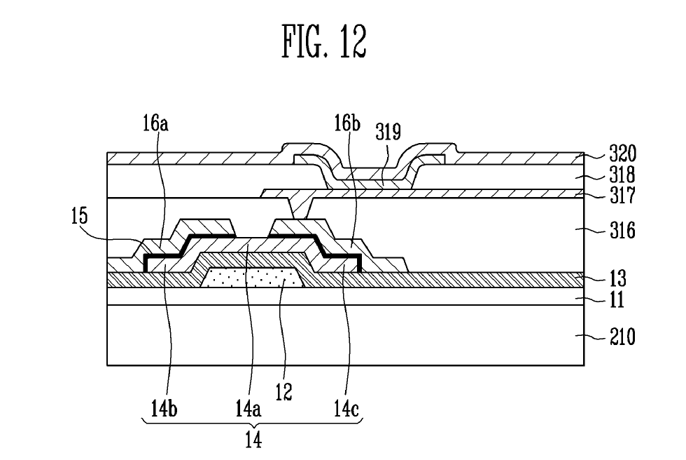

Referring to FIG. 12, the organic light emitting diode 300 comprises an anode electrode 317, a cathode electrode 320, and an organic thin film layer 319 formed between the anode electrode 317 and the cathode electrode 320. The organic thin film layer 319 is formed having a structure in which a hole transport layer, an organic light emitting layer, and an electron transport layer are stacked. Further, the organic thin film layer 319 may include a hole injection layer, a hole blocking layer, an electron blocking layer, and an electron injection layer, among others. Further, each of the layers of the organic light emitting diode 300 may include stacked layers. Also, the organic light emitting diode 300 can further include a thin film transistor to control the operation of the organic light emitting element 300 and a capacitor to maintain the signal.

The thin film transistor may have any one of the structures in FIGS. 1 to 4, and may be manufactured according to the manufacturing method described with reference to FIGS. 5A to 5E.

The organic light emitting element 300 including the thin film transistor as described above will be described in detail with reference to FIGS. 11A and 12. The buffer layer 11 is formed on the substrate 210 in the pixel region 220, and the gate electrode 12 is formed on the buffer layer 11. At this time, the pixel region 220 may be formed with the scan line 223 coupled to the gate electrode 12, and the non pixel region 230 may be formed with the scan line 224 extended from the pixel region 220 and the pad 228 that receives the signal from the outside.

The oxide semiconductor layer 14 is formed on the gate insulating layer 13 on the gate electrode 12 and electrically insulated from the gate electrode 12 by the gate insulating layer 13. The ohmic contact layer 15 is formed on the source region 14b and the drain region 14c of the oxide semiconductor layer 14, and the source and drain electrodes 16a and the 16b are formed to be coupled to the source region 14b and the drain region 14c through the ohmic contact layer 15. At this time, the pixel region 220 may be formed with the data line 226 coupled to one of the source and drain electrodes 16a and 16b, and the non-pixel region 230 may be formed with the data line 226 extended from the pixel region 220 and the pad 228 that receives the signal from the outside.

Thereafter, a planarization layer 316 to planarize the entire surface of the pixel region 220 is formed. A via-hole is formed in the planarization layer 316 so that a portion of the source electrode 16a or the drain electrode 16b is exposed, and the anode electrode 317 is formed and coupled to the source electrode 16a or the drain electrode 16b through the via-hole.

A pixel definition film 318 is formed on the planarization layer 316 so that a partial region (light emitting region) of the anode region 317 is exposed, and the organic thin film layer 319 is formed on the exposed anode electrode 317. The cathode electrode 320 is formed on the pixel definition film 318 to cover the organic thin film layer 319.

Referring to FIG. 11B, a sealing substrate 400 sealing the pixel region 220 is disposed on the upper surface of the substrate 210 on which the organic light emitting elements 300 are formed as described above. The sealing substrate 400 is bonded to the substrate 210 by a sealant 410 so that the display panel is completed.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thin film transistor, comprising:
a substrate;
an oxide semiconductor layer formed on the substrate and having a channel region, a source region, and a drain region;
a gate insulating layer formed on the substrate to cover the oxide semiconductor layer;
a gate electrode formed on the gate insulating layer and insulated from the oxide semiconductor layer by the gate insulating layer;
an ohmic contact layer formed on the source region and the drain region of the oxide semiconductor layer; and
a source electrode and a drain electrode respectively electrically coupled to the source region and the drain region through the ohmic contact layer,
wherein the ohmic contact layer is formed of a metal having a lower work function than work functions of the source electrode and the drain electrode.

2. The thin film transistor of claim 1, wherein the oxide semiconductor layer comprises zinc oxide (ZnO).

3. The thin film transistor of claim 2, wherein the oxide semiconductor layer is doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V).

4. The thin film transistor of claim 1, wherein the metal having a lower work function than the work functions of the source electrode and the drain electrode is selected from a group consisting of calcium (Ca), magnesium (Mg), potassium (K), and lithium (Li).

5. The thin film transistor of claim 1, wherein the metal having a lower work function than the work functions of the source electrode and the drain electrode is an alloy comprising a metal selected from a group consisting of calcium (Ca), magnesium (Mg), potassium (K), and lithium (Li).

6. The thin film transistor of claim 1, wherein the ohmic contact layer is disposed between with the source electrode and the oxide semiconductor layer and between the drain electrode and the oxide semiconductor layer.

7. The thin film transistor of claim 1, further comprising a buffer layer disposed between the substrate and the oxide semiconductor layer.

8. The thin film transistor of claim 1, further comprising:
an insulating layer formed on the substrate to cover the gate electrode,
wherein the source electrode and the drain electrode are disposed on the insulating layer and connected to the source region and the drain region through via holes formed in the insulating layer and the gate insulating layer.

9. The thin film transistor of claim 8, wherein the ohmic contact layer is disposed between the source electrode and the insulating layer, between the source electrode and the gate insulating layer, between the drain electrode and the insulating layer, and between the drain electrode and the gate insulating layer.

10. The thin film transistor of claim 8, wherein the ohmic contact layer is disposed on walls of the via holes formed in the insulating layer and the gate insulating layer.

11. A method of manufacturing a thin film transistor, the method comprising:
forming a gate electrode on a substrate;
forming a gate insulating layer on the gate electrode;
forming an oxide semiconductor layer having a channel region, a source region, and a drain region on the gate insulating layer;
forming an ohmic contact layer on the source region and the drain region of the oxide semiconductor layer; and
forming a source electrode and a drain electrode respectively electrically coupled to the source region and the drain region through the ohmic contact layer,
wherein the ohmic contact layer is formed of a metal having a lower work function than work functions of the source electrode and the drain electrode.

12. The method of claim 11, wherein the oxide semiconductor layer comprises zinc oxide (ZnO).

13. The method of claim 12, wherein the oxide semiconductor layer is doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V).

14. The method of claim 11, wherein the metal having a lower work function than the work functions of the source electrode and the drain electrode is selected from a group consisting of calcium (Ca), magnesium (Mg), potassium (K), and lithium (Li).

15. The method of claim 11, wherein the metal having a lower work function than the work functions of the source electrode and the drain electrode is an alloy comprising a metal selected from a group consisting of calcium (Ca), magnesium (Mg), potassium (K), and lithium (Li).

16. The method of claim 11, wherein the ohmic contact layer is formed to be disposed between the source electrode and the source region and between the drain electrode and the drain region.

17. The method of claim 11, further comprising forming a passivation layer on the oxide semiconductor layer of the channel region.

18. The method of claim 11, further comprising irradiating plasma on the source region and the drain region of the oxide semiconductor layer.

19. A flat panel display device having a thin film transistor, comprising:
a first substrate having disposed thereon:
first and second conductive lines, the first conductive lines disposed to cross the second conductive lines,
a plurality of pixels, each of the plurality of pixels having a first electrode and being defined by the first conductive lines and the second conductive lines, and
a plurality of thin film transistors electrically coupled to the first electrodes to control signals supplied to each of the pixels, respectively;
a second substrate having a second electrode formed thereon; and
a liquid crystal layer disposed in a sealed space between the first electrode and the second electrode,
wherein each of the thin film transistors comprises:
a gate electrode electrically connected to one of the first and second conductive lines,
an ohmic contact layer formed on a source region and a drain region of an oxide semiconductor layer, and
a source electrode and a drain electrode respectively electrically coupled to the source region and the drain region through the ohmic contact layer, one of the source electrode and the drain electrode being electrically connected to the other of the first and second conductive lines, and the other of the source electrode and the drain electrode being electrically connected to the first electrode,
wherein the ohmic contact layer is formed of a metal having a lower work function than work functions of the source electrode and the drain electrode.

20. The flat panel display device of claim 19, wherein the oxide semiconductor layer comprises zinc oxide (ZnO).

21. The flat panel display device of claim 20, wherein the oxide semiconductor layer is doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V).

22. The flat panel display device of claim 19, wherein the metal having a lower work function than the work functions of the source electrode and the drain electrode is selected from a group consisting of calcium (Ca), magnesium (Mg), potassium (K), and lithium (Li).

23. The flat panel display device of claim 19, wherein the metal having a lower work function than the work functions of the source electrode and the drain electrode is an alloy comprising a metal selected from a group consisting of calcium (Ca), magnesium (Mg), potassium (K), and lithium (Li).

24. A flat panel display device having a thin film transistor, comprising:
a first substrate having disposed thereon:
an organic light emitting element including a first electrode, an organic thin film layer, and a second electrode,
scan and data lines, and
the thin film transistor to control operation of the organic light emitting element; and
a second substrate disposed to face the first substrate,
wherein the thin film transistor comprises:
a gate electrode electrically connected to one of the scan lines;
an ohmic contact layer formed on a source region and a drain region of an oxide semiconductor layer, and
a source electrode and a drain electrode respectively electrically coupled to the source region and the drain region through the ohmic contact layer, one of the source electrode and the drain electrode being electrically connected to one of the data lines, and the other of the source electrode and the drain electrode being electrically connected to the first electrode,
wherein the ohmic contact layer is formed of a metal having a lower work function than work functions of the source electrode and the drain electrode.

25. The flat panel display device having the thin film transistor as claimed in claim 24, wherein the oxide semiconductor layer comprises zinc oxide (ZnO).

26. The flat panel display device of claim 25, wherein the oxide semiconductor layer is doped with at least one ion of gallium (Ga), indium (In), tin (Sn), zirconium (Zr), hafnium (Hf), cadmium (Cd), silver (Ag), copper (Cu), germanium (Ge), gadolinium (Gd), and vanadium (V).

27. The flat panel display device of claim 24, wherein the metal having a lower work function than the work functions of the source electrode and the drain electrode is selected from a group consisting of calcium (Ca), magnesium (Mg), potassium (K), and lithium (Li).

28. The flat panel display device of claim 24, wherein the metal having a lower work function than the work functions of the source electrode and the drain electrode is an alloy comprising a metal selected from a group consisting of calcium (Ca), magnesium (Mg), potassium (K), and lithium (Li).

29. A thin film transistor, comprising:
a substrate;
a gate electrode formed on the substrate;
a gate insulating layer formed on the substrate to cover the gate electrode;
an oxide semiconductor layer formed on the gate insulating layer, the oxide semiconductor layer being insulated from the gate electrode by the gate insulating layer, and the oxide semiconductor layer having a channel region, a source region, and a drain region;
an ohmic contact layer formed on the source region and the drain region of the oxide semiconductor layer; and
a source electrode and a drain electrode respectively electrically coupled to the source region and the drain region through the ohmic contact layer,
wherein the ohmic contact layer is formed of a metal having a lower work function than work functions of the source electrode and the drain electrode.

30. The thin film transistor of claim 29, wherein the metal having a lower work function than the work functions of the source electrode and the drain electrode is selected from a group consisting of calcium (Ca), magnesium (Mg), potassium (K), and lithium (Li).

31. The thin film transistor of claim 29, wherein the metal having a lower work function than the source electrode and the drain electrode is an alloy comprising a metal selected from a group consisting of calcium (Ca), magnesium (Mg), potassium (K), and lithium (Li).

32. The thin film transistor of claim 29, wherein the ohmic contact layer is formed between the source region and the source electrode and between the drain region and the drain electrode.

33. The thin film transistor of claim 32, wherein the ohmic contact layer is formed between source electrode and the gate insulating layer and between the drain electrode and the gate insulating layer.

34. The thin film transistor of claim 29, further comprising:
a passivation layer formed on the channel region of the oxide semiconductor layer.

35. The thin film transistor of claim 34, wherein the ohmic contact layer is formed between source electrode and the passivation layer and between the drain electrode and the passivation layer.
